(19) United States
(12) Patent Application Publication
(10) Pub. No.: US 2011/0140696 A1
(43) Pub. Date: Jun. 16, 2011

(54) SYSTEM AND METHOD FOR QUANTITATIVE SPECIES SIGNAL SEPARATION USING MR IMAGING

(76) Inventor: Huanzhou Yu, Sunnyvale, CA (US)

(21) Appl. No.: 12/638,422

(22) Filed: Dec. 15, 2009

(51) Int. Cl. G01R 33/48; G01R 33/44

(52) U.S. Cl. 324/309; 324/318

(57) ABSTRACT

A system and method for quantitative species signal separation in MR imaging is disclosed. An MR imaging apparatus includes an MRI system and a computer programmed to cause the MRI system to apply a pulse sequence and acquire multi-echo source data for the pulse sequence that includes a phase component and a magnitude component. The computer is further programmed to determine a first estimate of a first species content and a first estimate of a second species content based on the multi-echo source data, and determine a second estimate of the first species content and a second estimate of the second species content based on the multi-echo source data.

### BACKGROUND OF THE INVENTION

The invention relates generally to MR imaging and, more particularly, to a system and method for quantitative species signal separation in MR imaging using a two-step separation approach.

When a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{Z}, may be rotated, or “tipped”, into the x-y plane to produce a net transverse magnetic moment Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received NMR signals are digitized and processed to reconstruct the image using one of many well known reconstruction techniques.

In the field of MR imaging, water-fat separation techniques have been traditionally used in qualitative applications. One type of water-fat separation technique this is typically used is a multi-echo water-fat separation method that is based on the 2-pt or 3-pt “Dixon” reconstruction algorithms. All Dixon-based algorithms require complex source images. The phase information in the source images allows the estimation of the B₀ field/phase map. By utilizing a priori information of field map smoothness, water-fat swap that results from intrinsic ambiguity is avoided. However, these types of methods may be sensitive to any phase error in the source images, such as phase error caused by the eddy currents.

Alternative to water-fat separation methods that employ complex source images, there are also water-fat separation methods based on the magnitude of the source signals. These methods are completely insensitive to any phase error in the source data; however, such methods cannot take advantage of the smoothness of the B₀ field map to resolve water-fat ambiguity. As a result, fat-fraction, or fat/(water+fat), can only be uniquely determined in a 0-50% range.

While the above described water-fat separation techniques have been adequate for qualitative applications, there has recently been increasing interest in using water-fat separation techniques for quantitative applications, such as quantification of fatty infiltration of liver. The quantification of fatty infiltration of liver based on a fat-fraction quantification is more sensitive to errors than qualitative applications. For example, while a phase error in the multi-echo water-fat separation method employing Dixon-based algorithms is, in general, small and acceptable in most qualitative applications, they may be significant in quantitative applications.

It would therefore be desirable to have a system and method of MR imaging capable of fat-fraction quantification that achieves both high accuracy and high robustness.

### BRIEF DESCRIPTION OF THE INVENTION

Embodiments of the invention provide a system and method of quantitative species signal separation in MR imaging using a two-step separation approach.

In accordance with one aspect of the invention, an MR imaging apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images of a region-of-interest. The MR imaging apparatus also includes a computer programmed to cause the MRI system to apply a pulse sequence, acquire multi-echo source data for the pulse sequence that includes a phase component and a magnitude component, determine a first estimate of a first species content and a first estimate of a second species content based on the multi-echo source data, and determine a second estimate of the first species content and a second estimate of the second species content based on the multi-echo source data.

In accordance with another aspect of the invention, a computer program is stored on a computer readable storage medium, with the computer program comprising instructions that cause the computer to acquire a plurality of source image data sets for a region-of-interest of an imaging object, the plurality of source image data sets being acquired from multi-echo source data generated in response to a magnetic resonance (MR) pulse sequence and including a phase component and a magnitude component. The computer program also causes the computer to input the plurality of source image data sets into a first species separation algorithm, determine a quantity of a first species and a second species for each of a plurality of voxels in the region-of-interest from the first species separation algorithm, and input the plurality of source image data sets and the determined quantity of the first and second species into a second species separation algorithm. The computer program further causes the computer to re-determine the quantity of the first species and the second species for each of the plurality of voxels in the region-of-interest from the second species separation algorithm and generate images for the first species and the second species from the re-determined quantity of the first species and the second species.

In accordance with yet another aspect of the invention, a method for MR imaging of a region-of-interest including at least a first species and a second species therein includes applying a magnetic resonance (MR) pulse sequence and acquiring a plurality of image source signals from echoes generated in response to the MR pulse sequence, the plurality of image signals including signals from a first species and signals from a second species. The method also includes performing a first estimation of a first species content and a second species content based on phase data and magnitude data in the plurality of image source signals, performing a second estimation of the first species content and the second species content based on magnitude data in the plurality of image source signals, without use of phase data, and generating at least one image of the region-of-interest based on at least one of the first estimation and the second estimation.

Various other features and advantages will be made apparent from the following detailed description and the drawings.

### BRIEF DESCRIPTION OF THE DRAWINGS

The drawings illustrate embodiments presently contemplated for carrying out the invention.

In the drawings:

FIG. 1 is a schematic block diagram of an exemplary MR imaging system for use with an embodiment of the invention.

FIG. 2 is a flowchart of a technique for quantitative species signal separation in MR imaging using a two-step separation approach according to an embodiment of the invention.

FIGS. 3-5 are images from a phantom scan (FIG. 3), an in-vivo scan with a healthy volunteer (FIG. 4), and a patient scan with severe iron overload (FIG. 5), comparing image results from a one-step species separation approach and from a two-step species separation approach.

FIG. 6 is a flowchart of a technique for quantitative species signal separation in MR imaging using a two-step separation approach according to another embodiment of the invention.

### DETAILED DESCRIPTION OF THE PREFERRED EMBODIMENT

A system and method for species signal separation in MR imaging using a two-step separation approach is provided according to embodiments of the invention. While an embodiment of the invention is set forth below with respect to a system and method for performing a water-fat separation, separation of other species is also recognized as being within the scope of the invention. Additionally, it is recognized that more than two species could be separated by the systems and methods described below.

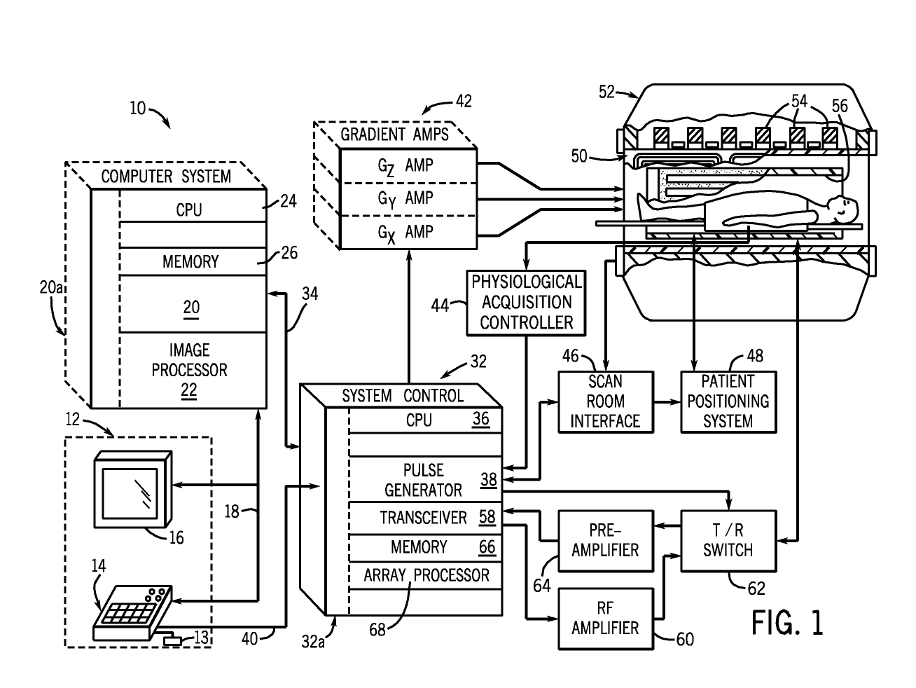

Referring to FIG. 1, the major components of a preferred magnetic resonance imaging (MRI) system 10 incorporating an embodiment of the invention are shown. The operation of the system is controlled from an operator console 12 which includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through a backplane 20a. These include an image processor module 22, a CPU module 24 and a memory module 26, which may include a frame buffer for storing image data arrays. The computer system 20 communicates with a separate system control 32 through a high speed serial link 34. The input device 13 can include a mouse, joystick, keyboard, track ball, touch activated screen, light wand, voice control, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a resonance assembly 52 which includes a polarizing magnet 54 and a whole-body RF coil 56. A transceiver module 58 in the system control 32 produces pulses which are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory. In response to commands received from the operator console 12, this image data may be archived in long term storage or it may be further processed by the image processor 22 and conveyed to the operator console 12 and presented on the display 16.

According to embodiments of the invention, computer system 20 of MR system 10 is programmed to perform a fat-fraction quantification analysis on a region-of-interest (ROI) of subject 12 using a two-step water-fat separation technique, where the relative amounts of water and fat within tissues of the ROI are quantified. In one step of the two-step water-fat separation technique, a water-fat separation algorithm is employed that uses complex source images to exploit the difference in chemical shifts between water and fat (i.e., phase shifts) in order to separate water and fat into separate images and estimate a B₀ field map. In another step of the two-step water-fat separation technique, magnitude images are employed in order to separate water and fat into separate images. Each of the first and second steps estimates a water and fat content of pixels/voxels of the images, with the water-fat content estimates of each step being used to determine a final or “fine-tuned” estimate of the water-fat content of each pixel/voxel.

Beneficially, water-fat content estimates derived from the step employing the complex source images allows for estimation of a B₀ field map, thereby enabling design of algorithms to utilize field map smoothness to avoid water-fat swap in the estimation that might result from intrinsic ambiguity. However, the water-fat content estimates derived from the step employing the complex source images may be sensitive to any phase error in the source images. To account for any such phase error, the step employing the magnitude source images provides water-fat content estimates that are insensitive to any phase error in the source data, as the phase component/information in the source data is removed from analysis of the water-fat content. As such, the two steps of the water-fat separation technique provide complementary outputs regarding the water-fat content estimate.

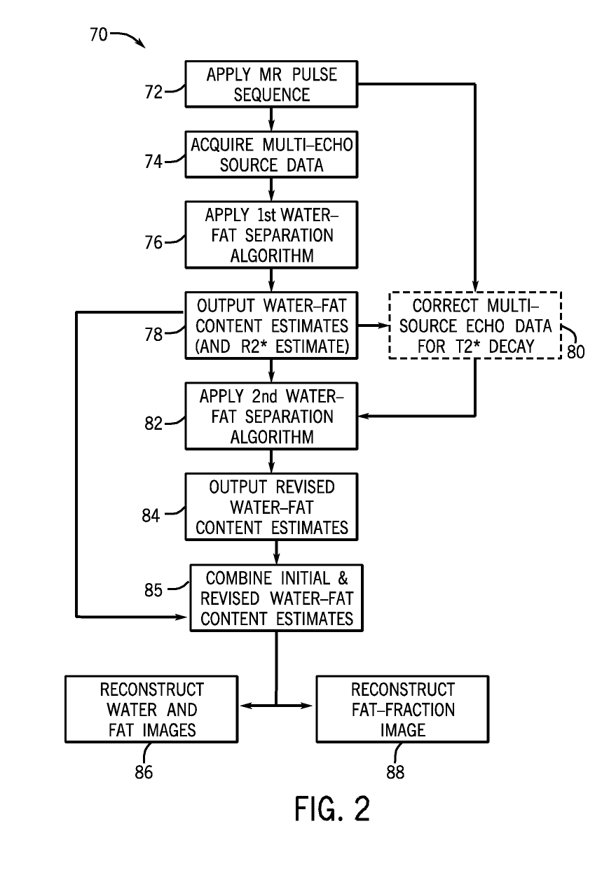

Referring now to FIG. 2, a computer implemented technique 70 (such as implemented by computer system 20 of FIG. 1) for performing a fat-fraction quantification analysis of a subject is shown, according to an exemplary embodiment of the invention. The technique 70 implements a “two-step” water-fat separation approach, where a “first step” of the two-step water-fat separation technique employs a water-fat separation algorithm that uses complex source images and the “second step” employs a water-fat separation algorithm that uses magnitude images. The estimates of the water-fat content output from the first step of the water-fat separation technique are input into the water-fat separation algorithm of the second step as an initial guess for the water-fat content, thereby avoiding water-fat ambiguity and providing a fast convergence in the second step estimation.

The technique 70 begins at block 72 with the application of a magnetic resonance (MR) pulse sequence configured to generate multiple echoes. According to embodiments of the invention, any of various pulse sequences that accommodate echo-coherent time MR imaging may be employed, such as: spin-echo, fast-spin-echo (FSE) spoiled gradient echo imaging (SPGR), steady state free precession (SSFP), or gradient recalled acquisition in steady state imaging (GRASS) pulse sequences, for example. Multi-echo source data or signals (i.e., image source signals) are acquired at block 74 from the echoes generated in response to the applied MR pulse sequence. The multi-echo source data is in the form of complex source image data sets in that the data includes both phase information and magnitude information (i.e., a phase component and a magnitude component). As such, the multi-echo source data includes therein phase information for both water signals and fat signals, with the phase information for the water and fat signals being separated due to chemical shifts between the water and the fat that are present over the plurality of echoes.

Upon acquisition of the multi-echo source data, a first water-fat separation algorithm is applied at block 76 (i.e., a “first step”). The first water-fat separation algorithm receives and analyzes the complex source data, i.e., both the phase information and the magnitude information in the multi-echo source data, in order to estimate a water content and a fat content of each voxel. That is, the first water-fat separation algorithm estimates water-fat content for each of the pixels/voxels of the tissue based on the phase data and magnitude data in the multi-echo source data, resulting in a water image and a fat image.

With respect to block 76, it is recognized that any of various water-fat separation algorithms may be applied that employ complex source signals to separate water and fat. According to embodiments of the invention, various multi-echo water-fat separation techniques based on Dixon reconstruction algorithms may be employed, wherein 2-, 3-, or other multi-point approaches use the echoes to sample the phase shift from the water-fat chemical shift. According to an exemplary embodiment of the invention, an Iterative Decomposition of Water and Fat with Echo Asymmetry and Least Square Estimation (IDEAL) technique that compensates for T2* decay (i.e., T2*−IDEAL) is applied at block 76 as the first step of the two-step water-fat separation technique 70. While block 76 is set forth below as being performed according to the T2*−IDEAL approach, it is recognized that other techniques that implement complex source images can also be used. Thus, the below embodiment implementing the T2*−IDEAL approach is not meant to limit the scope of the invention.

According to an implementation of T2*−IDEAL, a gradient-echo (GRE) imaging sequence is applied with three or more MRI signals being acquired. Under the assumption that the water and fat components that co-exist in the same voxel have a similar value of T2*, the signals (Sᵢ) of a voxel at the echo times (tᵢ, i=1, 2, 3, . . . k, k=number of echoes acquired) can be represented as:

$$\begin{matrix}{s}_{i} = ( w + f \cdot {e}^{j 2 πΔ f {t}_{i}} ) \cdot {e}^{j 2 π Ψ f {t}_{i}} \cdot {e}^{- {R}_{2}^{*} {t}_{i}} + {n}_{i} \\ = ( w + f \cdot {e}^{j 2 π Δ f {t}_{i}} ) \cdot {e}^{j 2 π ( Ψ + j {R}_{2}^{*} / 2 π ) {t}_{i}} + {n}_{i} \\ = ( w + f \cdot {e}^{j 2 π Δ f {t}_{i}} ) \cdot {e}^{j 2 π \hat{Ψ} {t}_{i}} + {n}_{i} ,\end{matrix} \qquad [ Eqn . 1 ]$$

where w and f denote the water and the fat components in this voxel, respectively, Δf is the chemical shift of fat with respect to water, Ψ represents the B₀ field inhomogeneity (in Hz), or field map, at this voxel, nᵢ is the noise in the signal, and R2*=1/T2*.

Furthermore, a “complex field map” is introduced as:

$$\hat{Ψ} = Ψ + j \frac{{R}_{2}^{*}}{2 π} . \qquad [ Eqn . 2 ]$$

The “complex field map,” \hat{Ψ}, the water content, and the fat content can then be calculated. First, the “complex field map,” \hat{Ψ}, is solved using an iterative algorithm summarized as:
1. Estimate the signal from each chemical species using an initial guess for the complex field map, \hat{Ψ}₀. A useful initial guess for \hat{Ψ}₀ is zero Hz.
2. Calculate the error to the complex field map, Δ\hat{Ψ}₀.
3. Recalculate \hat{Ψ}=\hat{Ψ}₀+αΨ.
4. Recalculate species signal, ŵ and \hat{f} with the new estimate of \hat{Ψ}.
5. Repeat the preceding three steps until Δ\hat{Ψ} is small (e.g., <1 Hz).
6. Spatially filter (smooth) the final complex field map, \hat{Ψ}, with a low-pass filter.
7. Recalculate the final estimate of the water and fat images.

The converged value of \hat{Ψ} is then decomposed with the real and imaginary parts assigned to the field map and the R2* map estimates. The source signals are demodulated by \hat{Ψ}, thereby correcting for both B₀ field inhomogeneity and T2* decay simultaneously, as denoted by:

Sᵢ′=Sᵢ·e^{-j2π\hat{Ψ}t}^{ᵢ}=W+f·e^{j2πΔft}^{ᵢ}+nᵢ·e^{-j2π\hat{Ψ}t}^{ᵢ} [Eqn. 3].

Considering all echoes, [Eqn. 3] can be formulated in a matrix form:

$$\begin{matrix}{s}^{′} = [ \begin{matrix}{s}_{1}^{′} \\ {s}_{2}^{′} \\ … \\ {s}_{k}^{′}\end{matrix} ] \\ = [ \begin{matrix}1 , {e}^{j 2 π Δ f {t}_{1}} \\ 1 , {e}^{j 2 π Δ f {t}_{2}} \\ … \\ 1 , {e}^{j 2 π Δ f {t}_{k}}\end{matrix} ] \cdot [ \begin{matrix}w \\ f\end{matrix} ] + [ \begin{matrix}{n}_{1} {e}^{- j 2 π \hat{Ψ} {t}_{1}} \\ {n}_{2} {e}^{- j 2 π \hat{Ψ} {t}_{2}} \\ … \\ {n}_{k} {e}^{- j 2 π \hat{Ψ} {t}_{k}}\end{matrix} ] \\ = A \cdot [ \begin{matrix}w \\ f\end{matrix} ] + {n}^{′} .\end{matrix} \qquad [ Eqn . 4 ]$$

Note that with the T2* correction, the variance of the noise (n′) is no longer equal for all echoes:

var(sᵢ′)=var(nᵢ′)=var(nᵢ)·e^{2R*t}^{ᵢ} [Eqn. 5].

[Eqn. 5] suggests that the source signals after correction for field map and T2* (s′) have less noise at earlier echoes, which is an intuitive result as signals decay away exponentially. To account for the different noise variance, water and fat components from a weighted least squares inversion are obtained, shown as:

$$[ \begin{matrix}w \\ f\end{matrix} ] = {( {A}^{T} \cdot W \cdot A )}^{- 1} \cdot {A}^{T} \cdot W \cdot {s}^{′} , \qquad [ Eqn . 6 ]$$

where the weights are given by W=diag(e^{-2R*t}^{₁}, e^{-2R*t}^{₂}, . . . , e^{-2R*t}^{ₖ}). The value of R2* is obtained from the iterative estimation of \hat{Ψ} as described earlier.

Estimates of the water content and fat content of the ROI are thus derived from [Eqn. 6] based on application of the T2*−IDEAL algorithm at block 76, in which the phase information and the magnitude information of the complex source data is analyzed. The estimates of the water content and fat content are then output at block 78. According to embodiments of the invention, the water-fat content estimates output from the T2*−IDEAL algorithm at block 78 are considered “rough” or “initial” estimates, in that it is recognized that these estimates may be sensitive to any phase error in the multi-echo source data (i.e., source images).

According to an embodiment of the invention where the T2*−IDEAL algorithm is employed as the first water-fat separation algorithm, the estimate of R2* derived from the T2*−IDEAL algorithm is also output at block 78 in addition to the output of water-fat content, as indicated in parentheses. Since the T2*−IDEAL algorithm mostly relies on the magnitude changes between the echoes to estimate R2*, the error due to the phase error is negligible for R2* estimation. Therefore, the R2* estimate or map generated from block 76 is treated as the final estimate for R2*. According to an exemplary embodiment of the invention, this final estimate for R2* is applied to the multi-echo source data at block 80 (shown in phantom) to correct the multi-echo source data for T2* decay. That is, the original multi-echo source data acquired at block 72 is corrected for T2* decay at block 80 based on the estimate for R2* output from the T2*−IDEAL algorithm at block 78. It is recognized that the estimate of R2* output at block 78 and the correction for T2* decay at block 80 are optional steps that are applied when using the T2*−IDEAL algorithm, but that may not be applied when other water-fat separation algorithms that employ complex source signals to separate water and fat are used.

Referring still to FIG. 2, upon output of the water-fat content estimates from the first water-fat separation algorithm at block 78, the technique continues with application of a second water-fat separation algorithm at block 82 (i.e., a “second step”). The second water-fat separation algorithm analyzes only the magnitude information included in the complex source data in order to estimate a water content and a fat content of the ROI, without making use of the phase information. That is, the second water-fat separation algorithm estimates water-fat content for each of the pixels/voxels of the tissue in the ROI based on the magnitude data in the multi-echo source data. The second water-fat separation algorithm analyzes the magnitude source images to provide water-fat content estimates that are insensitive to any phase error in the source data, as the phase component/information in the source data is removed from analysis of the water-fat content.

The second water-fat separation algorithm receives as an input, the corrected multi-echo source data output from block 80 (i.e., corrected for T2* decay). As set forth above, only the magnitude information (magnitude source images) from the complex multi-echo source data is input to the second water-fat separation algorithm. Thus, estimation of water and fat content in the second water-fat separation algorithm does not rely on the phase information of the source images, and thus such estimations are completely insensitive to any phase error in the source data. However, estimation of the water-fat content (i.e., reconstruction) is challenging due to the nonlinear and non-convex nature of the equation and the curve fitting may be very sensitive to an initial guess. Therefore, as another input to the second water-fat separation algorithm, the estimates of the water-fat content output from the T2*−IDEAL algorithm at block 78 are used as the initial guess for the actual water-fat content of the ROI. The water and fat content estimates from the T2*−IDEAL algorithm, while possibly not being quantitatively accurate due to the phase errors in the source images, should be very close to the true water and fat quantities. Therefore, they serve as an excellent initial guess for the estimation of water and fat in the magnitude source data of block 82, thereby ensuring fast convergence and further tuning of the estimates from block 76 and providing for efficient reconstruction of water and fat images.

With respect to block 82, it is recognized that any of various water-fat separation algorithms may be applied that employ only magnitude source signals for separating water and fat. According to an exemplary embodiment of the invention, a non-linear estimation algorithm, such as a “Gauss-Newton” search algorithm, is employed. In employing a Gauss-Newton algorithm, the magnitude signals (Sᵢ) from the multi-echo source data can be described as:

$$\begin{matrix}{\vert {S}_{i} \vert}^{2} = {\vert w + f \cdot {c}_{i} \vert}^{2} \\ = {w}^{2} + {\vert {c}_{i} \vert}^{2} {f}^{2} + 2 \cdot Re \{ {c}_{i} \} \cdot w \cdot f \\ = {w}^{2} + {a}_{i}^{2} \cdot {f}^{2} + 2 \cdot {b}_{i} \cdot w \cdot f ,\end{matrix} \qquad [ Eqn . 7 ]$$

where w and f are water and fat contents, i is the echo index (i=1 . . . nth, number of echoes), cᵢ is the fat signal modulation term, and aᵢ=|cᵢ| and bᵢ=Re{cᵢ}.

If fat is considered as a single peak with chemical shift of Δf, then:

cᵢ=e^{j2πΔf t}^{ᵢ} [Eqn. 8].

If a multi-peak fat spectrum with P discrete peaks is assumed, then:

$${c}_{i} = {\sum }_{p = 1}^{P} {α}_{p} \cdot {e}^{j 2 π Δ {f}_{p} {t}_{i}} . \qquad [ Eqn . 9 ]$$

For the single peak case where, aᵢ=1, w and f can be swapped in the equation. Therefore, if (w, f) is a set of solution of the equation, (f; w) is also a set of solution. This is the intrinsic ambiguity, which cannot be resolved without other a priori information.

An iterative algorithm set below in [Eqns. 10-15] is then used to solve the water and fat based on the above equation [Eqn. 7]. First, water and fat values from block 78 (w₁, f₁) are set as the initial guess according to:

ŵ:=w₁, \hat{f}:=f₁ [Eqn. 10].

Next, the signals corresponding to the current estimates are calculated as

|Ŝᵢ|²=ŵ²+aᵢ²·\hat{f}²+2·bᵢ·ŵ·\hat{f} [Eqn. 11].

The error terms are then calculated as:

|Sᵢ|²−|Ŝᵢ|²=2ŵ·Δw+2aᵢ²·\hat{f}·Δf+2·bᵢ·ŵ·Δf+2·bᵢ·\hat{f}·Δw=(2ŵ+2 bᵢ·\hat{f})·Δw+(2aᵢ²·\hat{f}+2·bᵢ·ŵ)·Δf [Eqn. 12],

and the matrix B is defined as:

$$B = [ \begin{matrix}2 \hat{w} + 2 \cdot {b}_{1} \cdot \hat{f} & 2 {a}_{1}^{2} \cdot \hat{f} + 2 \cdot {b}_{1} \cdot \hat{w} \\ 2 \hat{w} + 2 \cdot {b}_{2} \cdot \hat{f} & 2 {a}_{2}^{2} \cdot \hat{f} + 2 \cdot {b}_{2} \cdot \hat{w} \\ … & … \\ 2 \hat{w} + 2 \cdot {b}_{nte} \cdot \hat{f} & 2 {a}_{nte}^{2} \cdot \hat{f} + 2 \cdot {b}_{nte} \cdot \hat{w}\end{matrix} ] . \qquad [ Eqn . 13 ]$$

Therefore, a linear least squares inversion will give an estimate of the error terms (Δw and Δf) according to:

$$[ \begin{matrix}Δ w \\ Δ f\end{matrix} ] = {( {B}^{T} \cdot B )}^{- 1} \cdot {B}^{T} \cdot [ \begin{matrix}{\vert {S}_{1} \vert}^{2} - {\vert {\hat{S}}_{1} \vert}^{2} \\ {\vert {S}_{2} \vert}^{2} - {\vert {\hat{S}}_{2} \vert}^{2} \\ … \\ {\vert {S}_{nte} \vert}^{2} - {\vert {\hat{S}}_{nte} \vert}^{2}\end{matrix} ] . \qquad [ Eqn . 14 ]$$

The current estimates are then updated as:

ŵ=ŵ+Δw, \hat{f}=\hat{f}+Δf [Eqn. 15].

A determination is then made as to whether the iteration converges and/or the maximum number of iteration is reached. If the iteration has not converged and the maximum number of iterations has not been reached, then the iterative algorithm returns to [Eqn. 10]. If the iteration does converge and/or the maximum number of iterations has been reached, then the iterative algorithm terminates and it is determined that acceptable estimates for ŵ and \hat{f} have been obtained.

Estimates of the water content and fat content of the ROI are thus derived from [Eqn. 15] based on application of the Gauss-Newton algorithm at block 82, in which the magnitude information of the complex source data is analyzed. The estimates of the water content and fat content are then output at block 84. The estimates of the water content and fat content output at block 84 are considered “revised” or “updated” estimates, in that they are fine-tuned from the “rough” or “initial” water-fat content estimates derived from block 76 to account for any possible phase error.

Upon output of the revised/updated estimated water-fat content at block 84, the technique 70 continues with a combining of the initial estimates of the water content and fat content and the revised estimates of the water content and fat content at block 85. According to an exemplary embodiment of the invention, a weighted combination of the initial and revised estimates of the water content and fat content are determined at at block 85. From the weighted combination, water and fat images are reconstructed at block 86 and a fat-fraction image is reconstructed at block 88. The fat fraction image can be used to quantify fatty infiltration of a liver, for example, or provide for other quantitative analysis of a ROI. According to another embodiment of the invention, it is recognized that the water, fat, and fat-fraction images could be reconstructed directly from the revised/updated estimated water-fat content output at block 84, without the combining of the initial estimates of the water content and fat content and the revised estimates of the water content and fat performed at block 85.

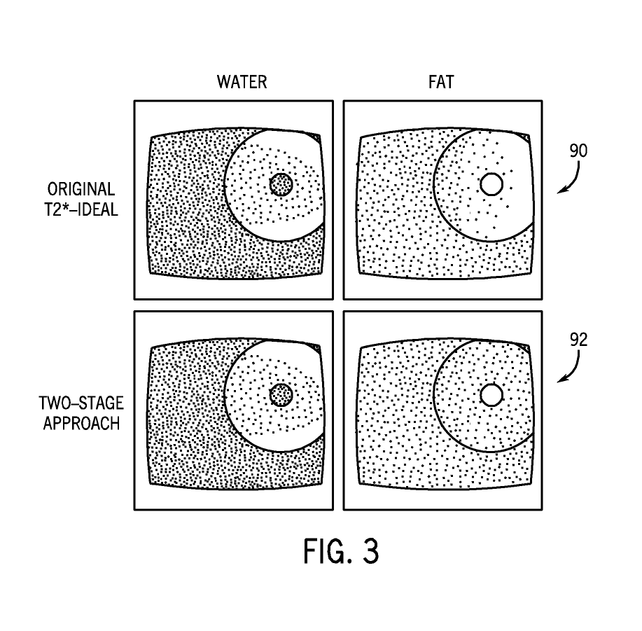

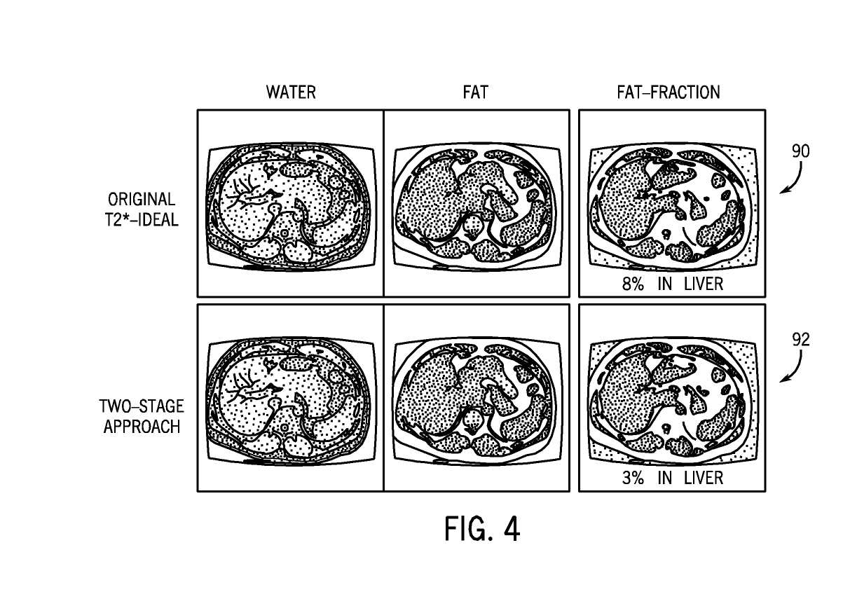

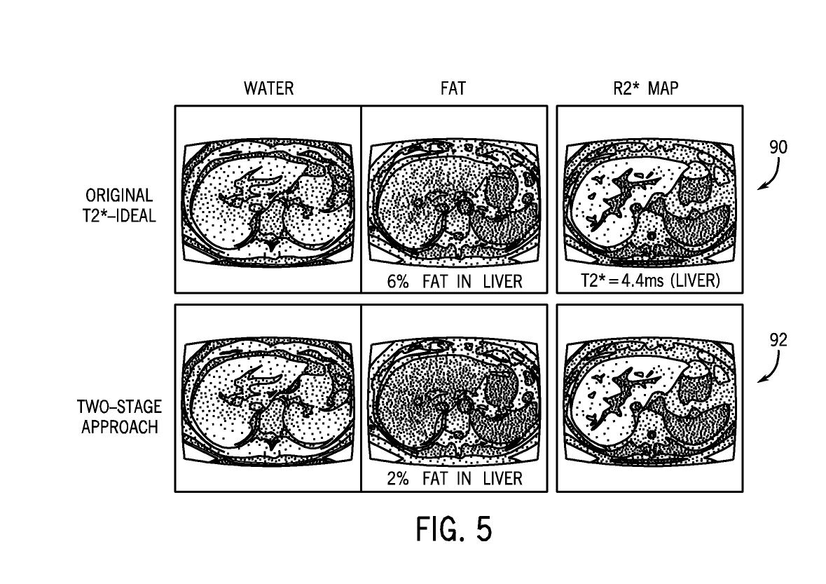

Referring now to FIGS. 3-5, results from a phantom scan (FIG. 3), an in-vivo scan with a healthy volunteer (FIG. 4), and a patient scan with severe iron overload (FIG. 5) are shown. In all three cases, six echoes were collected using a 2D-SPGR sequence (phantom scan) and a 3D-SPGR sequence (in-vivo scans). In each of FIGS. 3-5, images are shown comparing results from a single-step water-fat separation approach, images 90, and a two-step water-fat separation approach, images 92. With respect to the images 92 acquired by way of the two-step water-fat separation, such images were acquired using the two-step water-fat separation technique 70 shown and described with respect to FIG. 2, implementing the T2*−IDEAL algorithm and the Gauss-Newton algorithm to estimate water-fat content using the phase and magnitude information of complex source data in the first estimation step and only the magnitude information of the source data in the second estimation step, respectively. As can be seen in each of FIGS. 3-5, the images 90 acquired via a one-step water-fat separation technique (e.g., T2*−IDEAL) show water-fat separation based on the single estimation of the water-fat content using the complex source data, and show a “fatty liver” artifact in all three scans, reflected as a small amount of liver (or water) signal leaked into the fat image. The “fine tuned” images 92 shown in each of FIGS. 3-5 are generated based on the two-step estimation of the water-fat content using the complex source data in a first step and magnitude source data only in the second step. As can be seen in FIGS. 3-5, the fine tuned images 92 remove the “fatty liver” artifact that is present in images 90 generated by application of the T2*−IDEAL algorithm only. In the fine tuned images 92, water and liver have a noise-like appearance in the fat images, leading to more accurate fat-fraction measurement in a liver, for example.

While technique 70 (FIG. 2) described above is directed to a two-step water-fat separation technique where the “first step” employs a water-fat separation algorithm that uses complex source images and the “second step” employs a water-fat separation algorithm that uses magnitude images along with initial guesses output from the first step, it is recognized that other two-step water-fat separation techniques may be employed, according to additional embodiments of the invention.

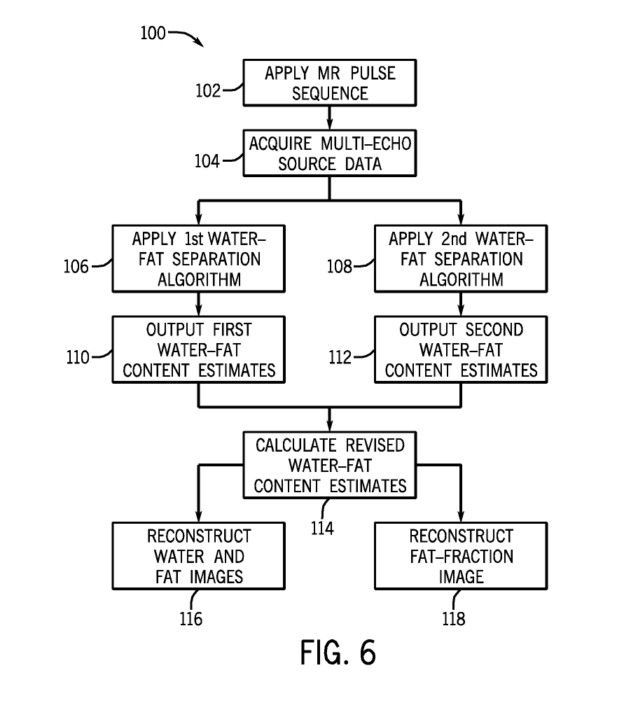

Referring now to FIG. 6 a computer implemented technique 100 (such as implemented by computer system 20 of FIG. 1) for performing a fat-fraction quantification analysis of a subject is shown, according to another embodiment of the invention. Technique 100 begins at block 102 with the application of a magnetic resonance (MR) pulse sequence configured to generate multiple echoes, such as a spin-echo, fast spin-echo (FSE), spoiled gradient echo imaging (SPGR), steady state free precession (SSFP), or gradient recalled acquisition in steady state imaging (GRASS) pulse sequence, for example. Multi-echo source data or signals (i.e., image source signals) are acquired at block 104 from the echoes generated in response to the applied MR pulse sequence. The multi-echo source data is in the form of complex source image data sets in that the data includes both phase information and magnitude information (i.e., a phase component and a magnitude component). As such, the multi-echo source data includes therein phase information for both water signals and fat signals, with the phase information for the water and fat signals being separated due to chemical shifts between the water and the fat that are present over the plurality of echoes.

Upon acquisition of the multi-echo source data, a first water-fat separation algorithm is applied at block 106 (i.e., a “first step”), and a second water-fat separation algorithm is applied at block 108 (i.e., a “second step”) that is independent of the first water-fat separation algorithm. As shown in FIG. 6, the first water-fat separation and the second water-fat separation algorithm can be applied simultaneously at blocks 106, 108, as they are applied independently from one another. That is, as compared to the technique 70 of FIG. 2, no output from the first water-fat separation algorithm is applied to the second water-fat separation algorithm as an initial guess.

With respect to the first water-fat separation algorithm applied at block 106, the first water-fat separation algorithm receives and analyzes the complex source data, i.e., both the phase information and the magnitude information in the multi-echo source data, in order to estimate a water content and a fat content of each voxel. That is, the first water-fat separation algorithm estimates water-fat content for each of the pixels/voxels of the tissue based on the phase data and magnitude data in the multi-echo source data, resulting in a water image and a fat image. It is recognized that any of various water-fat separation algorithms may be applied that employ complex source signals to separate water and fat. According to embodiments of the invention, various multi-echo water-fat separation techniques based on Dixon reconstruction algorithms may be employed, wherein 2-, 3-, or other multi-point approaches use the echoes to sample the phase shift from the water-fat chemical shift, such as the T2*−IDEAL set forth in detail above in [Eqns. 1-6].

With respect to the second water-fat separation algorithm applied at block 108, the second water-fat separation algorithm receives and analyzes only the magnitude information included in the complex source data in order to estimate a water content and a fat content of the ROI, without making use of the phase information. That is, the second water-fat separation algorithm estimates water-fat content for each of the pixels/voxels of the tissue in the ROI based on the magnitude data in the multi-echo source data. The second water-fat separation algorithm analyzes the magnitude source images to provide water-fat content estimates that are insensitive to any phase error in the source data, as the phase component/information in the source data is removed from analysis of the water-fat content. It is recognized that any of various water-fat separation algorithms may be applied that employ only magnitude source signals for separating water and fat, such as the “Gauss-Newton” search algorithm set forth in detail above in [Eqns. 7-15].

Referring still to FIG. 6, a first estimate of the water content and fat content provided by the first water-fat separation algorithm is output at block 110, and a second estimate of the water content and fat content provided by the second water-fat separation algorithm is output at block 112. Upon obtaining first and second estimates of the water-fat content at blocks 110, 112, technique 100 continues with calculation of a “final” or “revised” estimate of the water-fat content at block 114. According to an exemplary embodiment in order to determine a “final” estimate of the water-fat content, a weighted combination of the water-fat estimates from the first and second water-fat separation algorithms is calculated at block 114. Fat-fraction quantification and image reconstruction (i.e., water, fat, and fat-fraction images) is then performed based on this “final” estimate of the water-fat content at blocks 116 and 118.

It is recognized that other two-step water-fat separation techniques may be employed other than those set forth with respect to FIGS. 2 and 6 or that a reverse order of the “steps” may be applied, according to additional embodiments of the invention. In such an embodiment, the “first step” employs a water-fat separation algorithm that uses magnitude images, while the complex source-based water-fat separation technique is applied in the “second step”. The results from the “second step” will be used to resolve the water-fat ambiguity issue with the results from the “first step”. It is further recognized that other complex data and magnitude data formulations may be performed other than those set forth above in [Eqns. 1-15], and that the algorithm of the “second step” does not have to assume the same model as the algorithm of the “first step.” For example, the algorithm of the “second step” may estimate T2* of water and T2* of fat differently, while still making used of the “initial” T2* estimate output from the algorithm of the “first step.” In such an embodiment, the T2* estimate output from the algorithm of the first step would be an initial guess for each of the T2* of water and the T2* of fat estimated in the second step. As another example, the second water-fat separation algorithm may assume a multi-peak fat spectrum model while the first water-fat separation algorithm may assume a single peak fat spectrum model or vice versa.

A technical contribution for the disclosed method and apparatus is that is provides for a computer implemented technique for quantitative species signal separation in MR imaging using a two-step separation approach.

Therefore, according to one embodiment of the invention, an MR imaging apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images of a region-of-interest. The MR imaging apparatus also includes a computer programmed to cause the MRI system to apply a pulse sequence, acquire multi-echo source data for the pulse sequence that includes a phase component and a magnitude component, determine a first estimate of a first species content and a first estimate of a second species content based on the multi-echo source data, and determine a second estimate of the first species content and a second estimate of the second species content based on the multi-echo source data.

According to another embodiment of the invention, a computer program is stored on a computer readable storage medium, with the computer program comprising instructions that cause the computer to acquire a plurality of source image data sets for a region-of-interest of an imaging object, the plurality of source image data sets being acquired from multi-echo source data generated in response to a magnetic resonance (MR) pulse sequence and including a phase component and a magnitude component. The computer program also causes the computer to input the plurality of source image data sets into a first species separation algorithm, determine a quantity of a first species and a second species for each of a plurality of voxels in the region-of-interest from the first species separation algorithm, and input the plurality of source image data sets and the determined quantity of the first and second species into a second species separation algorithm. The computer program further causes the computer to re-determine the quantity of the first species and the second species for each of the plurality of voxels in the region-of-interest from the second species separation algorithm and generate images for the first species and the second species from the re-determined quantity of the first species and the second species.

According to yet another embodiment of the invention, a method for MR imaging of a region-of-interest including at least a first species and a second species therein includes applying a magnetic resonance (MR) pulse sequence and acquiring a plurality of image source signals from echoes generated in response to the MR pulse sequence, the plurality of image signals including signals from a first species and signals from a second species. The method also includes performing a first estimation of a first species content and a second species content based on phase data and magnitude data in the plurality of image source signals, performing a second estimation of the first species content and the second species content based on magnitude data in the plurality of image source signals, without use of phase data, and generating at least one image of the region-of-interest based on at least one of the first estimation and the second estimation.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An MRI apparatus comprising:
a magnetic resonance imaging (MRI) system having a plurality of gradient coils positioned about a bore of a magnet, and an RF transceiver system and an RF switch controlled by a pulse module to transmit RF signals to an RF coil assembly to acquire MR images of a region-of-interest; and
a computer programmed to:
cause the MRI system to apply a pulse sequence;
acquire multi-echo source data for the pulse sequence, the multi-echo source data including a phase component and a magnitude component;
determine a first estimate of a first species content and a first estimate of a second species content based on the multi-echo source data; and
determine a second estimate of the first species content and a second estimate of the second species content based on the multi-echo source data.

2. The MRI apparatus of claim 1 wherein the computer is programmed to apply a Dixon-based algorithm to determine the first estimates of the first species content and the second species content based on the phase component and magnitude component of the multi-echo source data.

3. The MRI apparatus of claim 2 wherein the computer is programmed to apply an iterative least-squares decomposition algorithm to determine the first estimates of the first species content and the second species content.

4. The MRI apparatus of claim 1 wherein the computer is programmed to apply a non-linear estimation algorithm to determine the second estimates of the first species content and the second species content based on the magnitude component of the multi-echo source data.

5. The MRI apparatus of claim 4 wherein the computer is programmed to:
input the magnitude component of the multi-echo source data into the non-linear estimation algorithm;
input the first estimates of the first species content and the second species content into the non-linear estimation algorithm as an initial guess of the second estimate of the first and second species content; and
determine the second estimate of the first species content and the second estimate of the second species content based on the magnitude component of the multi-echo source data and the first estimates of the first species content and the second species content.

6. The MRI apparatus of claim 5 wherein the computer is programmed to:
estimate a T2* decay for the multi-echo source data;
apply a correction to the multi-echo source data based on the estimated T2* decay; and
determine the second estimate of the first species content and the second estimate of the second species content based on the magnitude component of the corrected multi-echo source data and the first estimates of the first species content and the second species content.

7. The MRI apparatus of claim 1 wherein the first species comprises water and the second species comprises fat.

8. The MRI apparatus of claim 7 wherein the computer is programmed to quantify a fat fraction of the region-of-interest based on the first estimate of a water content and the first estimate of a fat content and based on the second estimate of the water content and the second estimate of the fat content.

9. The MRI apparatus of claim 8 wherein the computer is programmed to reconstruct a water image, a fat image, and a fat-fraction image from the first estimate of the water content and the first estimate of the fat content and based on the second estimate of the water content and the second estimate of the fat content.

10. The MRI apparatus of claim 1 wherein the computer is programmed to cause the MRI system to apply one of a spin-echo sequence, a fast spin-echo (FSE) sequence, a spoiled gradient echo imaging (SPGR) sequence, a steady state free precession imaging (SSFP) sequence, and a gradient recalled acquisition in steady state imaging (GRASS) sequence.

11. The MRI apparatus of claim 1 wherein the computer is programmed to calculate a weighted combination of the first estimates of the first and second species and the second estimates of the first and second species content.

12. A computer readable storage medium having stored thereon a computer program comprising instructions which when executed by a computer cause the computer to:
acquire a plurality of source image data sets for a region-of-interest of an imaging object, the plurality of source image data sets being acquired from multi-echo source data generated in response to a magnetic resonance (MR) pulse sequence and including a phase component and a magnitude component;
input the plurality of source image data sets into a first species separation algorithm;
determine a quantity of a first species and a second species for each of a plurality of voxels in the region-of-interest from the first species separation algorithm;
input the plurality of source image data sets and the determined quantity of the first and second species into a second species separation algorithm;
re-determine the quantity of the first species and the second species for each of the plurality of voxels in the region-of-interest from the second species separation algorithm; and
generate images for the first species and the second species from the re-determined quantity of the first species and the second species.

13. The computer readable storage medium of claim 12 having further instructions to cause the computer to determine the quantity of the first species and the second species for each of the plurality of voxels in the region-of-interest from a multi-point iterative least-squares decomposition algorithm based on the phase component and the magnitude component of the source image data sets.

14. The computer readable storage medium of claim 12 having further instructions to cause the computer to re-determine the quantity of the first species and the second species for each of the plurality of voxels in the region-of-interest from a non-linear estimation algorithm based on the magnitude component of the source image data sets.

15. The computer readable storage medium of claim 14 having further instructions to cause the computer to input the determined quantity of the first and second species into the non-linear estimation algorithm as an initial guess of the re-determined quantity of the first and second species.

16. The computer readable storage medium of claim 12 having further instructions to cause the computer to:
estimate a T2* decay for the plurality of source image data sets;
apply a correction to the plurality of source image data sets based on the estimated T2* decay to generate corrected source image data sets; and
input magnitude data from the corrected source image data sets into the second species separation algorithm, along with the determined quantity of the first and second species.

17. The computer readable storage medium of claim 12 wherein the first species comprises water and the second species comprises fat.

18. A method for MR imaging of a region-of-interest including at least a first species and a second species therein, the method comprising:
applying a magnetic resonance (MR) pulse sequence;
acquiring a plurality of image source signals from echoes generated in response to the MR pulse sequence, the plurality of image signals including signals from a first species and signals from a second species;
performing a first estimation of a first species content and a second species content based on phase data and magnitude data in the plurality of image source signals;
performing a second estimation of the first species content and the second species content based on magnitude data in the plurality of image source signals, without use of phase data; and
generating at least one image of the region-of-interest based on at least one of the first estimation and the second estimation.

19. The method of claim 18 wherein performing the first estimation of the first species content and the second species content comprises inputting the phase data and magnitude data in the plurality of image source signals into an iterative least-squares decomposition algorithm to determine the first estimates of the first species content and the second species content.

20. The method of claim 18 wherein performing the second estimation of the first species content and the second species content comprises:
inputting the magnitude data of the plurality of image source signals into a non-linear estimation algorithm;
inputting the first estimation of the first species content and the second species content into the non-linear estimation algorithm; and
performing the second estimation of the first species content and the second species content based on the magnitude data in the plurality of image source signals and the first estimation of the first and second species content.

21. The method of claim 20 further comprising:
estimating a T2* decay for the plurality of image source signals;
applying a correction to the plurality of image source signals based on the estimated T2* decay to generate corrected image source signals;
inputting magnitude data from the corrected plurality of image source signals into the non-linear estimation algorithm; and
performing the second estimation of the first species content and the second species content based on the magnitude data in the corrected plurality of image source signals and the first estimation of the first and second species content.

22. The method of claim 21 wherein generating the at least one image of the region-of-interest comprises generating the at least one image of the region-of-interest based on the second estimation of the first and second species content.

23. The method of claim 18 further comprising calculating a weighted combination of the first estimation of the first and second species content and the second estimation of the first and second species content; and
wherein generating the at least one image of the region-of-interest comprises generating the at least one image of the region-of-interest based on the weighted combination.

24. The method of claim 18 wherein the first species comprises water and the second species comprises fat; and
wherein generating the at least one image of the region-of-interest comprises generating a water image, a fat image, and a fat fraction image.
